(19) United States
(12) Patent Application Publication
(10) Pub. No.: US 2026/0293555 A1
(43) Pub. Date: Sep. 24, 2026

(54) SUBSTRATE PROCESSING METHOD AND SUBSTRATE PROCESSING APPARATUS

(71) Applicant: Tokyo Electron Limited, Minato-ku (JP)

(72) Inventors: Tatsuya SANO, Nirasaki City (JP); Kwangpyo CHOI, Nirasaki City (JP)

(21) Appl. No.: 19/560,671

(22) Filed: Mar. 9, 2026

(30) Foreign Application Priority Data
Mar. 18, 2025 (JP) 2025-043043

(51) Int. Cl. H10P 50/28; H10P 72/00

(52) U.S. Cl. CPC H10P 50/283; H10P 72/0421

(57) ABSTRACT

A substrate processing method includes accommodating a substrate having a space, wherein a wall surface forming the space has a target film; a first process of supplying a first gas to the substrate; a second process of exhausting the processing container; a third process of supplying a second gas to the substrate, which reacts with the target film together with the first gas to generate a reaction product on the wall surface; a fourth process of exhausting the processing container; a reaction process of repeating a cycle of sequentially performing the first to third processes, and the fourth process so as to generate the reaction product, and of setting a temperature of the substrate to a first temperature; and a removal process of removing the reaction product by setting the temperature of the substrate after the reaction process to a second temperature higher than the first temperature.

### CROSS-REFERENCE TO RELATED APPLICATION

This application is based upon and claims the benefit of priority from Japanese Patent Application No. 2025-043043, filed on Mar. 18, 2025, the entire contents of which are incorporated herein by reference.

### TECHNICAL FIELD

The present disclosure relates to a substrate processing method and a substrate processing apparatus.

### BACKGROUND

In semiconductor device manufacturing processes, there is a process of forming, for example, a wiring layer on a semiconductor wafer (silicon wafer, hereinafter referred to as a "wafer"), which is a substrate. In order to reduce resistance between the wafer and the wiring layer, there is also a process of forming, for example, a metal film. When forming such a metal film, the wafer may be exposed to the atmosphere or the like, so that an oxide film may be formed on the surface of the wafer. If this oxide film remains and a contact for establishing electrical connection between the wiring layer and a surface layer of the wafer is formed, this may become a factor that increases a resistance value of the contact. Therefore, a process of removing the oxide film is performed prior to the formation of the metal film.

For example, Patent Document 1 describes etching an SiOₓ film by supplying hydrogen fluoride (HF) gas and ammonia (NH₃) gas to the SiOₓ film.

### Prior Art Document

### Patent Document

Patent Document 1: Japanese patent laid-open publication No. 2024-129577

### SUMMARY

According to one embodiment of the present disclosure, there is provided a substrate processing method, including: a process of accommodating, in a processing container, a substrate having a space including a first recess opening at a front surface of the substrate and a plurality of second recesses opening at different positions of the first recess in a thickness direction of the substrate, wherein a wall surface forming the space has a target film; a first process of supplying a first gas to the substrate inside the processing container from a first tank pressurized by storing the first gas; a second process of exhausting an interior of the processing container in a state in which supply of the first gas into the processing container is stopped; a third process of supplying a second gas to the substrate inside the processing container from a second tank pressurized by storing the second gas, the second gas reacting with the target film together with the first gas remaining in the space to generate a reaction product on the wall surface; a fourth process of exhausting the interior of the processing container in a state in which supply of the second gas into the processing container is stopped; a reaction process of repeating a cycle of sequentially performing the first process, the second process, the third process, and the fourth process so as to generate the reaction product from a front surface side toward a rear surface side of the substrate, and of setting a temperature of the substrate to a first temperature while repeating the cycle such that the reaction product formed during a previous cycle remains on the substrate during a subsequent cycle; and a removal process of removing the reaction product as a gas by setting the temperature of the substrate after the reaction process is performed to a second temperature higher than the first temperature.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view illustrating a substrate processing apparatus according to an embodiment.

FIG. 2 is a schematic diagram illustrating a substrate disposed within a processing module of the substrate processing apparatus.

FIG. 3 is a longitudinal cross-sectional side view illustrating a space forming layer of a substrate.

FIG. 4 is a longitudinal cross-sectional side view illustrating the processing module.

FIG. 5 is a partial longitudinal cross-sectional side view illustrating a change in a front surface layer of a substrate on which substrate processing is performed.

FIG. 6 is a partial longitudinal cross-sectional side view illustrating a change in the front surface layer of the substrate on which substrate processing is performed.

FIG. 7 is a partial longitudinal cross-sectional side view illustrating a change in the front surface layer of the substrate on which substrate processing is performed.

FIG. 8 is a partial longitudinal cross-sectional side view illustrating a change in the front surface layer of the substrate on which substrate processing is performed.

FIG. 9 is a partial longitudinal cross-sectional side view illustrating a change in the front surface layer of the substrate on which substrate processing is performed.

FIG. 10 is a partial longitudinal cross-sectional side view illustrating a change in the front surface layer of the substrate on which substrate processing is performed.

FIG. 11 is a partial longitudinal cross-sectional side view illustrating a change in the front surface layer of the substrate on which substrate processing is performed.

FIG. 12 is a time chart of a reaction process of substrate processing.

FIG. 13 is a longitudinal cross-sectional side view illustrating the outline of a substrate before substrate processing in an evaluation test.

FIG. 14 is a graph illustrating the results of an evaluation test according to a comparative example.

FIG. 15 is a graph illustrating the results of an evaluation test according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiments

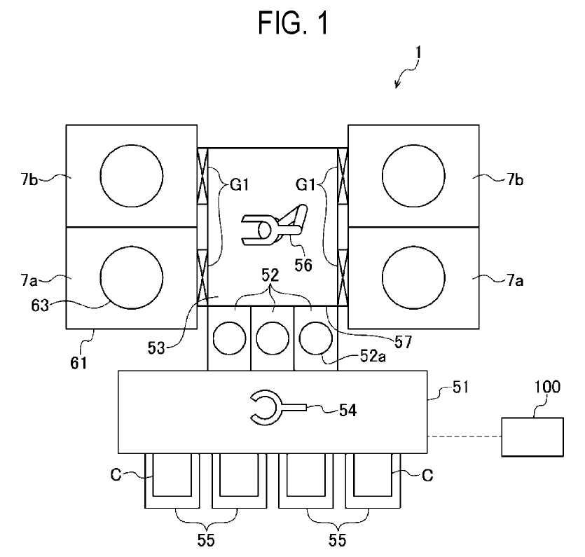

FIG. 1 is a plan view illustrating a substrate processing apparatus according to an embodiment. A substrate processing apparatus 1 is a multi-chamber system including processing modules 7a and 7b each performing processing on a substrate W, which is a wafer. The substrate W is sequentially processed by the processing modules 7a and 7b so that, for example, etching of a target film (e.g., a silicon oxide film (SiOₓ film)) provided on a front surface of the substrate W is performed. The processing module 7a is configured to perform a reaction process for modifying the SiOₓ film on the front surface of the substrate W to generate a reaction product ((NH₄)SiF₆), AFS), and in the reaction process, a plurality of process gases, specifically, HF gas and NH₃ gas, is supplied to the substrate W. The processing module 7b is configured to perform a removal process for vaporizing and removing the reaction product (AFS) by heating the substrate W. As described above, the substrate processing apparatus 1 is configured as an apparatus that performs a chemical oxide removal (COR) process on the SiOₓ film formed on the substrate W.

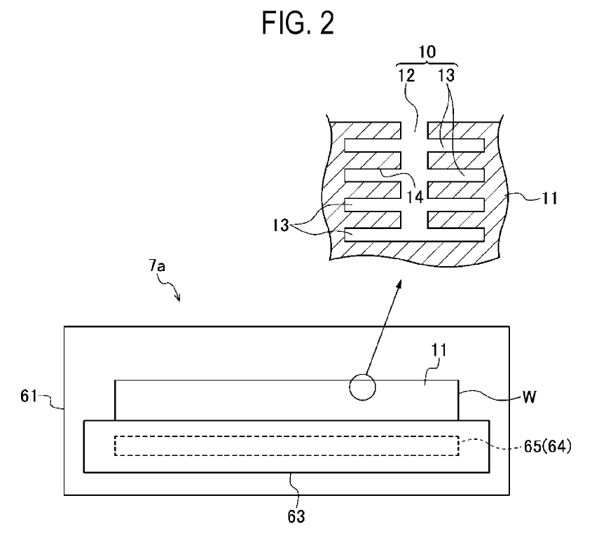

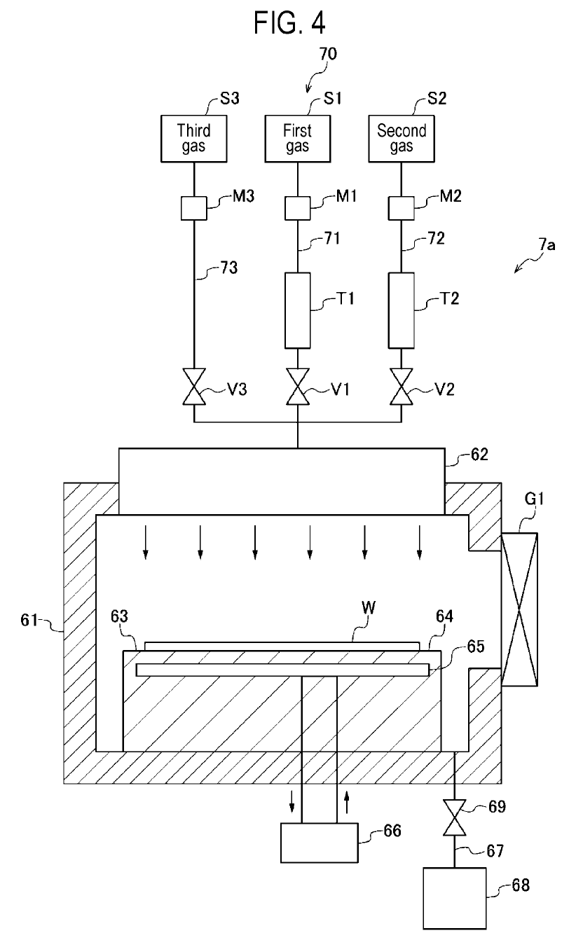

As illustrated in FIG. 2, the substrate W on which processing of the embodiment is performed has a plurality of spaces 10 previously formed by, for example, an etching process on a front surface side (corresponding to an upper surface during substrate processing) of the substrate W among front and rear surfaces, which are main surfaces. In FIG. 2, one space 10 among the plurality of spaces 10 is illustrated. Further, in FIG. 2, the processing module 7a to be described later with reference to FIG. 4 is shown in a simplified manner, and the substrate W is illustrated in a state of being placed on a substrate stage 63 of the processing module 7a for performing processing. In this state, the front surface of the substrate W is directed upward.

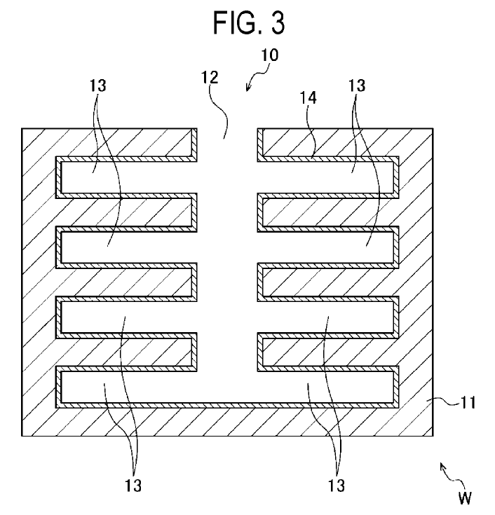

A layer which is provided on the substrate W and in which the space 10 is formed is referred to as a space forming layer 11. FIG. 3 illustrates a longitudinal cross-sectional side surface of the space forming layer 11. The space 10 will be described assuming that the substrate W is in a processing orientation (i.e., the space 10 is open upward). The space forming layer 11 is provided with the above-described SiOₓ film 14 as the target film, and the SiOₓ film 14 forms a thin film surrounding the space 10. Accordingly, a wall surface forming the space 10 are formed by the SiOₓ film 14.

The space 10 includes a first recess 12 that extends in a thickness direction of the substrate W from a front surface opening of the substrate W toward a rear surface side of the substrate W, and a plurality of second recesses 13 that are open at different positions on an inner wall surface forming the first recess 12. The second recesses 13 are arranged at positions facing each other through the first recess 12 and a plurality of the second recesses 13 is arranged from the front surface side toward the rear surface side (downward side) of the substrate W.

More specifically, each second recess 13 extends in a direction intersecting, specifically orthogonal to, an extending direction of the first recess 12. The second recesses 13 are arranged in line symmetry and in multiple stages with respect to a central axis along which the first recess 12 extends. In FIG. 2, an example in which the second recesses 13 have four stages is illustrated, but in reality, there are several tens of stages (e.g., 100 stages or more). In this case, the length of each second recess 13 in the extending direction (lateral direction) is, for example, several hundred nanometers (nm), and the depth of the first recess 12 in the depth direction (vertical direction) is, for example, about 10 µm, such that the space 10 is elongated vertically relative to a lateral width.

Accordingly, when a process gas is supplied to the substrate W, the space 10 forms a flow path that is branched into a plurality of paths as the space 10 extends downward from the front surface opening of the substrate W. Further, downstream ends of this flow path (a lower end of the first recess 12 and terminal ends of the second recesses 13) are disposed within the substrate W and are closed. Since a large number of branches is formed in this manner, the area of the inner wall surface forming the flow path (the space 10) is much larger than the area of the inner wall surface in the case in which a space having the same volume as the space 10 is formed by depressing down the front surface of the substrate into a recess shape.

Further, as described above, since the depth of the first recess 12 constituting the space 10 is relatively large, and a large number of second recesses 13 is formed as branch paths in the depth direction of the first recess 12, pressure loss of the process gas becomes relatively high in a lower side of the first recess 12, which is a deep portion of the space 10, and in the second recesses 13 opening at the lower side. As a result, in the space 10, it is difficult for the process gas to enter the deep portion due to the pressure loss, and also it is difficult for the process gas to enter the deep portion because the inner wall surface has a large area and the process gas is consumed (mostly adsorbed) at an upper side Thereby, depending on a configuration of a device that supplies the process gas or processing conditions, a range in which the process gas is sufficiently adsorbed onto the wall surface of the space 10 may be limited only to the upper side of the space 10, and there is a concern that it may become difficult to sufficiently adsorb the process gas onto the wall surface of the deep portion of the space 10. That is, there is a concern that it may become difficult to remove the SiOₓ film 14 from the entire inner wall surface forming the space 10.

The substrate processing apparatus 1 of the present embodiment is configured to prevent occurrence of such a problem. Since this will be described in detail later, a brief description is given here. The processing module 7a repeats a cycle of sequentially supplying the HF gas and the NH₃ gas as process gases in the reaction process to the substrate W by high-pressure discharge and performing relatively short vacuum evacuation between the supplies of the gases. In the repetition of the cycle, in order to allow a relatively large amount of the process gases to reach the lower side of the space 10 by using a reaction product (AFS) formed on the inner wall surface of the upper side of the space 10, the temperature of the substrate W is controlled so as to suppress sublimation of the reaction product (AFS) during performing the cycle. By such processing in the processing module 7a, the SiOₓ film 14 formed on the entire inner wall surface of the space 10 is converted into the reaction product (AFS) 15.

The space forming layer 11 is, for example, a Si layer, and the SiOₓ film 14 serving as the target film may be formed by oxidation of a front surface portion of the Si layer through exposure to the atmosphere. The space forming layer 11 may be formed by SiOₓ, identical to the SiOₓ film 14. The space forming layer 11 may also be a Si-containing compound including another material such as germanium (Ge). The space forming layer 11 may be formed of a material other than the Si-containing compound composed of Si such as Si, SiOₓ, or SiGe.

Hereinafter, the processing module 7a will be described with reference to FIG. 4, which is a longitudinal cross-sectional side view. The processing module 7a includes a processing container 61 whose interior is evacuated to a vacuum atmosphere, a shower head 62 provided at an upper portion of the processing container 61, and the substrate stage 63 provided within the processing container 61. A transfer port for the substrate W, provided on a side wall of the processing container 61, is opened and closed by a gate valve G1.

The shower head 62 is disposed in the processing container 61 so as to face the substrate stage 63, and an interior thereof forms a gas diffusion space (not shown). A lower portion of the shower head 62 constitutes a shower plate, and a plurality of through holes is formed in the shower plate so as to uniformly discharge various gases supplied to the gas diffusion space toward the front surface of the substrate W placed on the substrate stage 63. A discharge port to which a gas supply mechanism 70 to be described later is connected is formed in the upper center of the shower head 62.

The substrate stage 63 is disposed such that an upper surface thereof faces the shower plate. Three substrate support pins (not shown) are provided inside the substrate stage 63 so as to be movable up and down at a placement position of the substrate W. The substrate support pins are inserted into through holes formed in the substrate stage 63 so as to protrude from or retract into the upper surface of the substrate stage 63, thereby allowing the substrate W to be delivered between a vacuum transfer mechanism 56 (shown in FIG. 1) to be described later and the substrate stage 63.

Further, the substrate stage 63 is provided with a temperature adjustor 64 for adjusting the temperature of the substrate W. The temperature adjustor 64 includes a fluid flow path 65 provided inside the substrate stage 63 and a chiller 66 connected to the flow path 65. By circulating a fluid temperature-adjusted by the chiller 66 through the flow path 65, the substrate W placed on the substrate stage 63 is set to a desired temperature.

An exhaust pipe 67, an upstream end of which forms an exhaust hole, is connected to a lower portion of the processing container 61, and, for example, an automatic pressure control (APC) valve serving as a pressure control valve 69 is interposed in the exhaust pipe 67. An exhaust mechanism 68, including a vacuum pump or the like, is provided at a downstream end of the exhaust pipe 67. As an opening degree of the pressure control valve 69 is increased by a controller 100 to be described later, an exhaust amount from the exhaust pipe 67 by the exhaust mechanism 68 increases, and pressure inside the processing container 61 decreases. Exhaust from the exhaust pipe 67 is continuously performed during processing of the substrate W. The processing module 7a further includes the gas supply mechanism 70 for supplying various gases, such as the process gases described above, into the processing container 61 through the shower head 62.

The gas supply mechanism 70 includes pipes 71, 72, and 73, downstream sides of which join each other and are connected to the discharge port of the shower head 62 described above. The pipes 71 and 72 are flow paths for supplying, for example, the HF gas as a first gas and the NH₃ gas as a second gas, respectively, with tanks T1 and T2 interposed in the respective pipes. The pipe 71 is provided with a valve V1, a tank (first tank) T1, a flow rate adjustor M1, and an HF gas supply source S1 interposed therein in this order towards an upstream side. The pipe 72 is provided with a valve V2, a tank (second tank) T2, a flow rate adjustor M2, and an NH₃ gas supply source S2 interposed therein in this order toward the upstream side. The flow rate adjustors M1 and M2 are each constituted by a mass controller and a valve and are configured to adjust flow rates of the HF gas and the NH₃ gas supplied respectively from the HF gas supply source S1 and the NH₃ gas supply source S2 and also to switch on and off state of the supply of each gas.

The pipe 73 is a flow path for supplying an inert gas (e.g., argon (Ar) gas or nitrogen (N₂) gas) as a third gas and is provided with a valve V3, a flow rate adjustor M3, and an inert gas supply source S3 interposed therein in this order towards the upstream side. The inert gas supplied from the pipe 73 is a purge gas for purging the HF gas and NH₃ gas remaining on a downstream side of the pipes 71 to 73 and for purging the inside of the processing container 61 and is supplied, for example, at the same flow rate except during a fourth process.

Each of the tanks T1 and T2 is provided with a pressure sensor (not shown) to transmit a detection signal relating to pressure inside each of the tanks T1 and T2 to the controller 100 to be described later. The controller 100 detects the pressure inside each of the tanks T1 and T2 based on the detection signal. For example, when supplying gases to the tanks T1 and T2, the controller 100 controls the flow rate adjustors M1 and M2 to stop the supply of gases to the tanks T1 and T2 when the pressures inside the tanks T1 and T2 rise to preset pressures. The HF gas and the NH₃ gas are supplied to the tanks T1 and T2, respectively, and are stored therein so that the tanks T1 and T2 are pressurized. Thereafter, the HF gas and the NH₃ gas are supplied toward the inside of the processing container 61 by opening the valves V1 and V2. Accordingly, discharge pressures of these gases from the shower head 62 become relatively high. The pressures inside the tanks T1 and T2 when discharging the HF gas and the NH₃ gas are, for example, 1200 Pa (9 Torr).

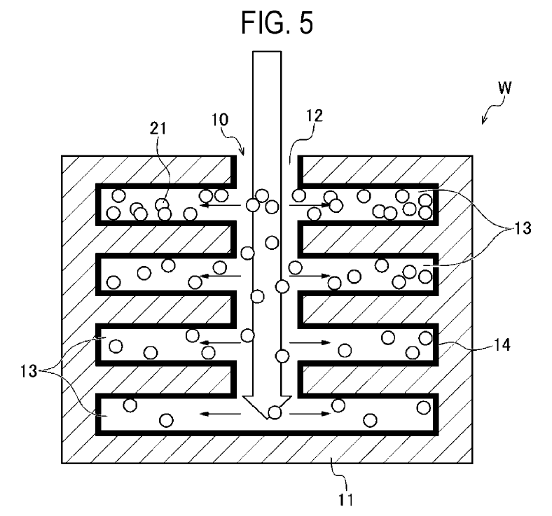

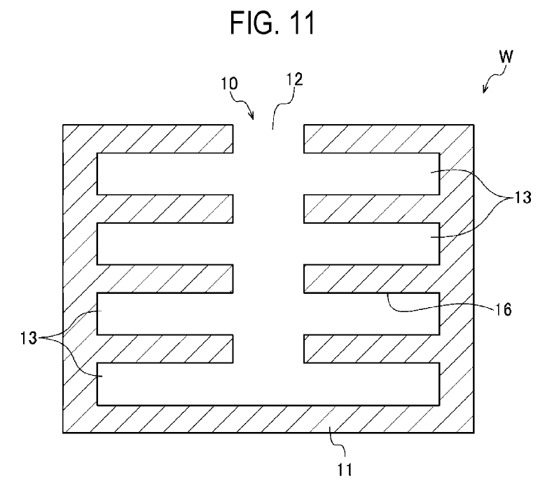

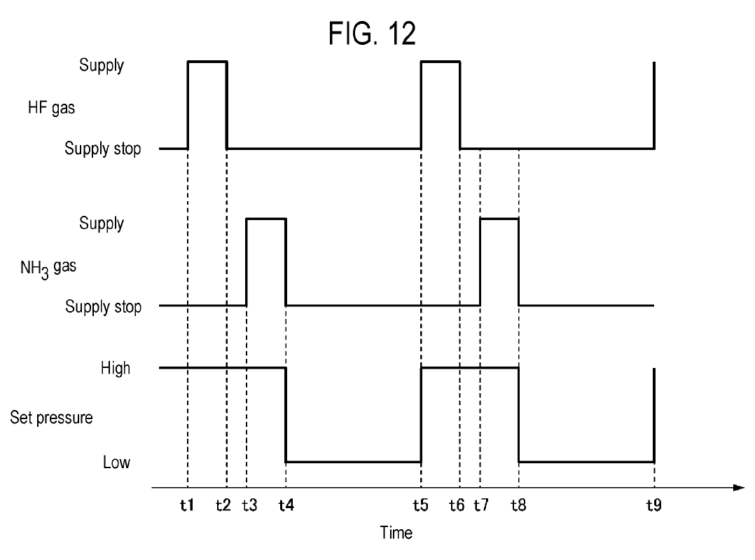

FIGS. 5 to 11 are partial longitudinal cross-sectional side views illustrating changes in a front surface layer of a substrate on which substrate processing of the present example is performed, and the substrate processing according to the present disclosure will now be described with reference thereto. FIGS. 5 to 10 illustrate the substrate W processed by the processing module 7a, and FIG. 11 illustrates the substrate W after processing by the processing module 7b. In FIGS. 5 to 11, only the HF gas (first gas) 21 and the NH₃ gas (second gas) 22, which are process gases, are illustrated as gases supplied to the substrate W, and illustration of the inert gas (purge gas as the third gas) is omitted. A description is also appropriately given with reference to a time chart of FIG. 12 illustrating a change in a supply duration of each gas supplied into the processing container 61 and a change in a set pressure inside the processing container 61. Since adjustment of the set pressure inside the processing container 61 is performed by adjusting an opening degree of the pressure control valve 69 of the exhaust pipe 67 described above, this chart indicates a change in the opening degree of the pressure control valve 69.

The substrate W placed on the substrate stage 63 is set to a relatively low temperature by the temperature adjustor (first temperature adjustor) 64 of the processing module 7a, and the pressure inside the processing container 61 is set to a vacuum atmosphere at a relatively high pressure (FIG. 2). For example, the pressure inside the processing container 61 is set to a first set pressure, for example, 200 Pa to 667 Pa (1.5 Torr to 5 Torr), and the temperature of the substrate stage 63 is set to 0 degrees C or higher and 60 degrees C or lower (a first temperature), more specifically, for example, 35 degrees C. By setting the pressure and temperature as described above, vaporization and removal of the reaction product (AFS) generated in the reaction process are prevented. Further, by setting the temperature to be relatively low as described above, adsorption efficiency of the supplied process gases onto the inner wall surface of the space 10 is improved, and modification of the SiOₓ film 14 can be effectively performed.

During processing in the processing module 7a, a temperature set value is not changed, but as shown in the chart, a pressure set value is changed. Further, such set temperature and set pressure are merely set values, and the actual substrate temperature and the actual pressure inside the processing container may change depending on each processing performed in the reaction process. Specifically, for example, due to rapid gas supply for a short period of time from the tanks T1 and T2, the actual pressure may deviate from the set pressure.

After the temperature of the substrate W and the pressure inside the processing container 61 are set to the above-described values and supply of the inert gas into the processing container 61 is started by opening the valve V3, the valve V1 is opened and the HF gas 21 stored in the tank T1 is supplied to the substrate W inside the processing container 61 (time t1, FIG. 5) as a first process. The HF gas 21 discharged at high pressure under the vacuum atmosphere flows into the first recess 12 from the front surface opening and flows downward. Each time the HF gas 21 passes through a plurality of openings along the way, the HF gas 21 is branched and flows toward the terminal end of each second recess 13. While the HF gas 21 flows in this manner, the flow rate and pressure of the HF gas 21 decrease.

By being supplied at high pressure from the tank T1 in this manner, a relatively large amount of the HF gas 21 can be supplied to the deep portion of the space 10. However, since adsorption of the HF gas onto the target film (SiOₓ film 14) on the wall surface forming the space 10 progresses while flowing through the space 10, the amount of molecular adsorption of the HF gas 21 onto a lower wall surface of the space 10 is small compared to the amount of molecular adsorption of the HF gas 21 onto an upper wall surface of the space 10.

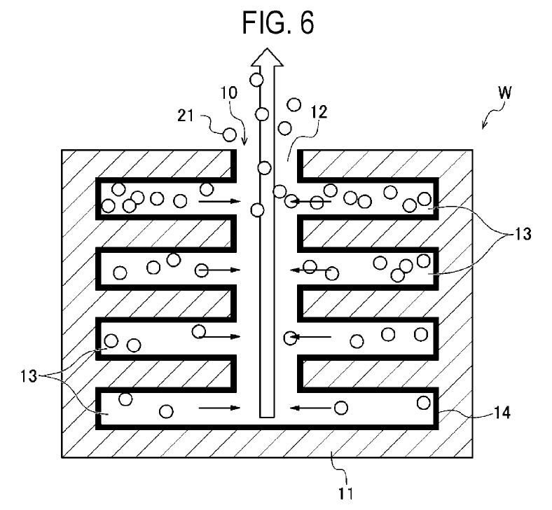

As a second process, the valve V1 is closed to stop supply of the HF gas 21 into the processing container 61, so that no process gas is supplied into the processing container 61 and exhaust is performed (time t2, FIG. 6). In this second process, since the gas is not supplied to the substrate W at high pressure (i.e., not supplied via the pressurized tank), the HF gas 21 accumulated at and around the front surface opening of the space 10 is removed by exhaust of the inside of the processing container 61, and the pressure at and around the front surface opening decreases. Then, the HF gas 21 remaining in the space 10 and not adsorbed onto the wall surface flows toward the openings, and during this process, adsorption onto the wall surface proceeds.

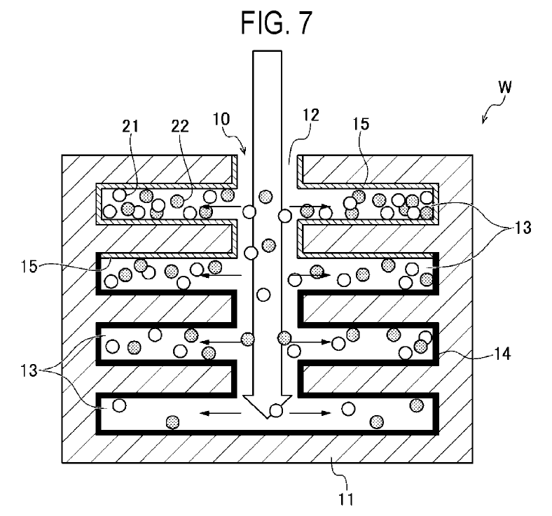

As a third process, the valve V2 is opened and the NH₃ gas 22 stored in the tank T2 is supplied to the substrate W inside the processing container 61 (time t3, FIG. 7). Since the pressure in the vicinity of the openings has been reduced in the second process and since the NH₃ gas 22 is supplied via the tank T2, a relatively large amount of the NH₃ gas 22 among the NH₃ gas 22 supplied into the processing container 61 is introduced into the space 10, flows downward through the first recess 12 in the same manner as the HF gas 21, and also flows into the second recesses 13 in the process.

A duration from time t2 to time t3 (i.e., an execution time of the second process) is set to be relatively short. Therefore, during flow of the NH₃ gas 22, a relatively large amount of the HF gas 21 remains, particularly, on the upper side of the space 10, in a state of not being adsorbed onto the wall surface. The NH₃ gas 22 is mixed with and agitated together with the HF gas 21 and flows through the space 10 as described above. By such agitation of the HF gas 21 and the NH₃ gas 22 in the relatively small space 10, these process gases are relatively likely to collide with the wall surface. Accordingly, adsorption of these process gases onto the target film (SiOₓ film 14) on the wall surface is promoted.

In portions of the target film (SiOₓ film 14) on the wall surface where both the NH₃ gas 22 and the HF gas 21 are adsorbed, the target film (SiOₓ film 14) on the wall surface reacts with these gases and is thereby converted into the reaction product (AFS) 15. Since the NH₃ gas 22, like the HF gas 21, is adsorbed in a smaller amount onto the target film (SiOₓ film 14) on the lower wall surface of the space 10 than onto the target film (SiOₓ film 14) on the upper wall surface of the space 10, formation of the reaction product (AFS) 15 tends to proceed more easily on the upper side of the space 10 than on the lower side of the space 10.

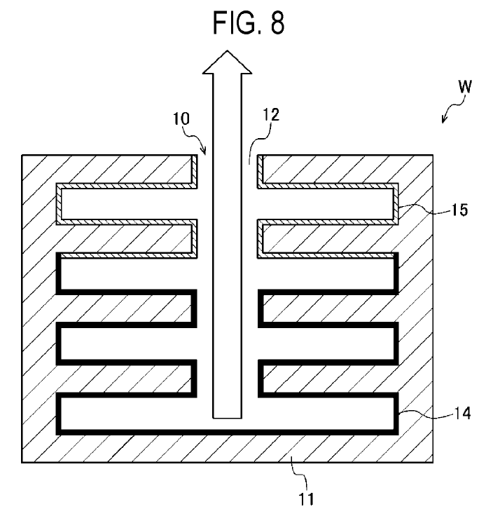

As a fourth process, the valves V2 and V3 are closed to stop supply of the NH₃ gas 22 and the inert gas into the processing container 61, so that these gases are not supplied into the processing container 61 and exhaust is performed. In addition, together with closing of the valves V2 and V3, the set pressure inside the processing container 61 is lowered from the first set pressure kept up to that time to a second pressure (time t4, FIG. 8). The second pressure corresponds to a fully exhausted state and is, for example, 1.3 Pa (10 mTorr) or higher and 133 Pa (1 Torr) or lower. By lowering the set pressure in this manner, the HF gas 21 and the NH₃ gas 22 in the space 10 of the substrate W are sufficiently removed, and the reaction between the HF gas 21 and the NH₃ gas 22 within the space 10 is suppressed, thereby suppressing generation of an unintended reaction product. Since the substrate temperature is set to be relatively low as described above, the reaction product (AFS) 15 does not vaporize and remains even when the pressure inside the processing container 61 is reduced in this fourth process.

The first to fourth processes described above are sequentially performed as one cycle, and the cycle is repeatedly performed a plurality of times. Further, after time t4, the pressure inside the processing container 61 increases so as to return to the first set pressure, and the valve V1 is opened and the HF gas 21 stored in the tank T1 is supplied to the substrate W inside the processing container 61 (time t5). Accordingly, the fourth process ends (i.e., a first cycle ends), and the first process is performed again (i.e., a second cycle is started). In order to sufficiently remove the HF gas 21 and the NH₃ gas 22, a duration from time t4 to time t5, which is an execution time of the fourth process, is longer than a duration from time t2 to time t3, which is an execution time of the second process.

As the cycles are repeated, the processing module 7a repeatedly performs the operations described at times t1 to t5. Further, the second cycle is performed at times t5 to t9 in the chart, and the same operations as those performed at times t2,t3, t4, and t1 are performed at times t6, t7, t8, and t9, respectively, in the processing module 7a.

In cycles after the second cycle, both the HF gas 21 and the NH₃ gas 22 are supplied to the substrate W in the same manner as in the first cycle. However, in portions of the target film (SiOₓ film 14) on the wall surface of the space 10 of the substrate W where the SiOₓ film 14 has already been modified into the reaction product (AFS) 15, no reaction with these process gases occurs. That is, consumption of the process gases due to reaction in the portions modified into the reaction product (AFS) 15 is prevented. Further, as described above, since each of the HF gas 21 and the NH₃ gas 22 is discharged into the processing container 61 at high pressure by use of the tanks T1 and T2, the gases can relatively easily reach the deep portion of the space 10.

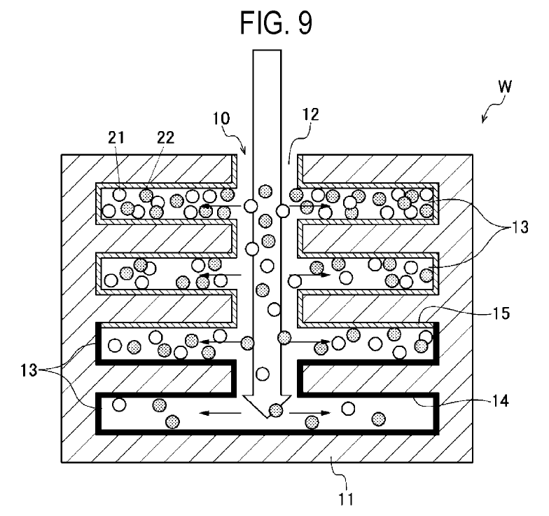

Accordingly, in the second cycle, a sufficient amount of the HF gas 21 and the NH₃ gas 22 for reaction is supplied to and adsorbed onto a portion lower than a region converted into the reaction product (AFS) 15 in the first cycle in the target film (SiOₓ film 14) on the wall surface forming the space 10, so that the lower side portion becomes the reaction product (AFS) 15 (FIG. 9). In the subsequent third cycle process, a sufficient amount of the HF gas 21 and the NH₃ gas 22 for reaction is supplied to and adsorbed onto a lower portion lower than a region converted into the reaction product (AFS) 15 in the second cycle in the wall surface forming the space 10, so that the target film (SiOₓ film 14) on the wall surface of the lower portion becomes the reaction product (AFS) 15. As the number of such cycle processes increases, the amount of the HF gas 21 and the NH₃ gas 22 supplied to a lower portion of the space 10 increases, and a range in which the reaction product (AFS) 15 is formed expands downward in the space 10.

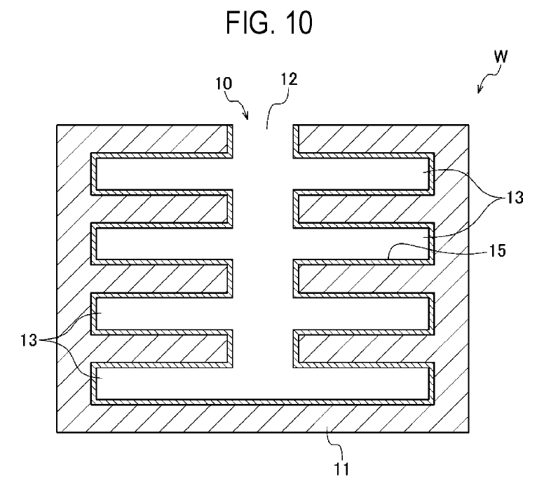

After a predetermined number of cycles is repeated and the entire target film (SiOₓ film 14) on the wall surface forming the space 10 becomes the reaction product (AFS) 15 (FIG. 10), repetition of the cycles is terminated. In other words, processing in the processing module 7a is completed. Subsequently, the substrate W in which all of the inner wall surface becomes the reaction product (AFS) 15 in the processing module 7a is transferred to the processing module 7b and subjected to heat treatment to vaporize and remove the reaction product (AFS) 15 (FIG. 11). A second temperature, which is the temperature of the substrate during this heat treatment, is higher than the previously described first temperature and is a temperature at which the reaction product (AFS) 15 vaporizes under an atmosphere inside the processing container, for example, higher than 60 degrees C and 200 degrees C or lower, specifically, 175 degrees C. After the reaction product (AFS) 15 is removed, the first recess 12 and the second recesses 13 constituting the space 10 are each slightly expanded by an amount corresponding to the removed reaction product (AFS) 15, and an inner wall surface 16 after removal of the reaction product (AFS) 15 is composed of the space forming layer 11.

A series of processes performed in the processing module 7a will now be supplementarily described. In the first process and the third process, since the gases stored in the tanks T1 and T2 are supplied at high pressure, execution times of these processes are set to be relatively short. Specifically, each execution time of these processes in one cycle is, for example, 0.1 seconds to 5 seconds. That is, a duration between times t1 and t2, a duration between times t3 and t4, a duration between times t5 and t6, and a duration between times t7 and t8, shown in the chart, are, for example, 0.1 seconds to 5 seconds.

The second process is performed such that, as described above, when the NH₃ gas 22 is supplied to the substrate W in the subsequent third process, the HF gas 21 remaining in the space 10 and the NH₃ gas 22 can sufficiently react with the target film (SiOₓ film; 14). If the execution time of the second process is excessively long, a large amount of the HF gas 21 is discharged from the space 10, making it difficult for the reaction to occur. Therefore, the execution time of the second process (a duration from time t2 to time t3 and a duration from time t6 to time t7 in the chart) is set to be relatively short, for example, shorter than the execution time of the fourth process (a duration from time t4 to time t5 and a duration from time t8 to time t9 in the chart), as described above. As a specific example, the execution time of the second process is 0.1 seconds or less and is set to be equal to or shorter than the execution times of the first process and the third process described above.

Up to now, the execution time of the fourth process has been described as being set to be relatively long and longer than the execution time of the second process. However, the present disclosure is not limited thereto, and the execution time of the fourth process may be set within a range of 0.1 seconds to several tens of seconds. Accordingly, the execution time of the fourth process may be set to be the same as the execution time of the second process. In addition, in the fourth process, the supply of the inert gas into the processing container is stopped in the above example in order to further reduce the pressure inside the processing container 61 and to rapidly remove the HF gas 21 and the NH₃ gas 22 from the space 10. However, the supply of the inert gas may also be performed in the fourth process.

Returning to FIG. 1, a configuration of the substrate processing apparatus 1 will be described. In addition to the processing modules 7a and 7b, the substrate processing apparatus 1 includes a loader module 51, load lock modules 52, and a vacuum transfer module 53. The loader module 51, the load lock modules 52, and the vacuum transfer module 53 are arranged side by side in this order in a straight line in a front-rear direction when viewed in a plan view. In the following description of the substrate processing apparatus 1, a side on which the loader module 51 is located is referred to as a front side, and a side on which the vacuum transfer module 53 is located is referred to as a rear side.

The loader module 51 includes a housing, the interior of which is at atmospheric pressure, a transfer mechanism 54 for the substrate W provided inside the housing, and load ports 55. In this example, four load ports 55 are provided side by side on the front side of the housing in a left-right direction. A transfer container C for accommodating the substrate W, called a front opening unified pod (FOUP), is placed on each of the load ports 55. The transfer mechanism 54 is configured, for example, by an articulated arm movable in the left-right direction and is capable of transferring the substrate W between the transfer container C placed on each of the load ports 55 and each of the load lock modules 52.

In this example, three load lock modules 52 are provided side by side in the left-right direction when viewed from the front side. Each of the load lock modules 52 has a housing, and the housing is connected to the loader module 51 and the vacuum transfer module 53 via gate valves, which are not shown, provided respectively on the front side and the rear side of the housing. When the gate valves (not shown) on the front side and the rear side of the housing are closed, pressure inside the housing is capable of being varied between atmospheric pressure and vacuum pressure. Further, a stage 52a on which the substrate W is placed is provided inside the housing. A plurality of substrate support pins (not shown) is provided in the stage 52a so as to be protrudable from the surface thereof and the stage 52a is configured to allow delivery of the substrate W to and from the transfer mechanism 54 and the vacuum transfer mechanism 56 which will be described later, both of which access the corresponding load lock module 52. The gate valves connected to the load lock modules 52 and the aforementioned gate valve G1 are closed except when necessary for the transfer of the substrates W, thereby isolating an atmosphere between the modules.

The vacuum transfer module 53 includes a housing 57 and a vacuum transfer mechanism 56 provided inside the housing 57. One end of an exhaust pipe is connected to the housing 57, and the inside of the housing 57 is exhausted by a vacuum exhausts mechanism (not shown) connected via the exhaust pipe and is maintained under vacuum. As the vacuum exhaust mechanism, a turbomolecular pump, for example, may be used to maintain high vacuum inside the housing 57, thereby effectively suppressing oxidation of the inner wall surface 16 of the substrate W after the removal of the reaction products (AFS) 15.

Two processing modules are connected to each of the left and right sides of the housing 57 of the vacuum transfer module 53, and the two processing modules are arranged in a front-rear direction. In the shown example, among a total of four processing modules, two are shown as the processing module 7a and the other two are shown as the processing module 7b. Each of the processing modules 7a and 7b is connected to the housing 57 through the gate valve G1. The delivery of the substrate W between these processing modules 7a and 7b and the load lock modules 52 is performed by the vacuum transfer mechanism 56, which is composed of, for example, an articulated arm capable of moving forward, backward, left, and right. The delivery of the substrate W between the processing modules 7a and 7b is also similarly performed by the vacuum transfer mechanism 56.

The processing module 7b will be briefly described focusing on structural differences from the processing module 7a. The processing module 7b is provided with a heater (a second temperature adjustor) using, for example, resistance heating in a substrate stage. The heater sets the temperature of the placed substrate to a temperature higher than the substrate temperature in the reaction process in the processing module 7a, for example, higher than 60 degrees C and 200 degrees or lower, specifically, to 175 degrees C. The gas supply mechanism includes a pipe capable of supplying the inert gas, similar to the pipe 73 of the processing module 7a, and the processing module 7b exhausts the inside of the processing container while supplying the inert gas during heat treatment.

The substrate processing apparatus 1 includes the controller 100, which is a computer, and the controller 100 includes a program. The program incorporates instructions (steps) for performing the above-described reaction process, removal process, and substrate transfer process. The program is stored in a storage medium, for example, a compact disc, a hard disk, a DVD, a non-volatile memory, and the like and is read from the storage medium and installed in the controller 100.

The controller 100 outputs a control signal to each part of the substrate processing apparatus 1 according to the program and controls the operation of each part. Specifically, the controller 100 controls the operations of the processing modules 7a and 7b, the opening and closing of the gate valve G1, the operation of the transfer mechanism 54 or the vacuum transfer mechanism 56, the operation of the exhaust mechanism, and the pressure switching operation of the load lock modules 52. Control of the operations of the processing modules 7a and 7b includes, for example, control regarding the temperature of the substrate W by the temperature adjustor, the set pressure inside the processing container, and supply or cutoff of each gas into the processing container 61.

A transfer route of the substrate W in the substrate processing apparatus 1 will now be described. The substrate W is first transferred in order of the transfer container C → loader module 51 → load lock module 52 → vacuum transfer module 53 → processing module 7a. The substrate W on which the reaction product (AFS) 15 have been generated in the processing module 7a is then transferred in order of the processing module 7a → vacuum transfer module 53 → processing module 7b.

Then, the substrate W from which the reaction product (AFS) 15 has been removed in the processing module 7b is transferred in order of the vacuum transfer module 53 → load lock module 52 → loader module 51 and is returned to the transfer container C.

Further, in the substrate processing apparatus 1 of FIG. 1, although only the processing modules 7a and 7b are shown as being connected to the vacuum transfer module 53, the present disclosure is not limited to such an apparatus configuration. Any processing module among the plurality of processing modules 7a and the plurality of processing modules 7b shown in the drawing may be a processing module 7c (not shown) that performs arbitrary post-processing, such as film formation in the space 10, on the substrate W from which the SiOₓ film 14 has been removed. Then, the substrate W that has been transferred and processed in order of the processing modules 7a, 7b, and 7c by the vacuum transfer module 53 may be returned to the transfer container C.

### Modifications

Although, in the reaction process of the present disclosure, the discharge pressures of the HF gas and the NH₃ gas from the tanks T1 and T2 are set to be the same, the present disclosure is not limited thereto and the discharge pressures may be set differently. Further, although, in the reaction process of the present disclosure, the HF gas is supplied in the first process and the NH₃ gas is supplied in the third process, the present disclosure is not limited thereto. For example, these gases may be supplied in the reverse order of the processes. In addition, for example, these gases may be simultaneously discharged at high pressure in at least any one of the first process or the third process. In this case, in order to prevent these gases from reacting in the gas supply mechanism 70 or in the shower head 62, the pipes 71 and 72 may not be joined and the gases may be supplied through different flow paths within the shower head.

Further, although the gases used in the first and third processes are each supplied once from the respective tanks T1 and T2 to achieve gas supply for a short period of time, the present disclosure is not limited thereto. For example, a plurality of tanks T1 and a plurality of T2 may be provided, and in the first and third processes, the discharge of each gas may be performed consecutively multiple times, so that high-pressure discharge for a relatively longer time than high-pressure discharge in the present disclosure may be performed. Further, by intermittently discharging gases multiple times from the plurality of tanks T1 and the plurality of tanks T2 at relatively short intervals, the first process to the third process may be performed multiple times, with the second process, which is relatively short vacuum evacuation, interposed therebetween. As one example, when the first and third processes are each performed twice within a cycle, the first process → second process → first process → second process → third process → second process → third process → fourth process may be performed.

Although the reaction process and the removal process are performed in different processing containers of the processing module 7a and the processing module 7b, these processes may be performed in the same processing container 61, for example, in the processing module 7a. In that case, a heater may be provided in addition to the temperature adjustor 64 to adjust the temperature of the substrate W to the temperature described above. Further, although the substrate temperature is set to a constant temperature during the reaction process, the present disclosure is not limited thereto and the substrate temperature may be changed. Although the set pressure is maintained constant in the first to third processes and the fourth process, the present disclosure is not limited thereto and the set pressure may also be changed.

Further, although using the NH₃ gas has been described, the present disclosure is not limited thereto. For example, amine gas can be used. As the amine gas, amine such as trimethylamine (TMA) can be used. In addition to TMA, various amine compound gases such as dimethylamine, dimethylethylamine, diethylamine, triethylamine, monotertiarybutylamine, pyrrolidine, pyridine, and the like can be used. Further, as another specific example of the amine compound, a compound (1,1,1-trifluorodimethylamine or the like) in which some or all of C-H bonds of the above compound are replaced with C-F bonds can be used.

In the above processing example, although the HF gas and the NH₃ gas are supplied to the substrate W in the first process and the third process, respectively, the NH₃ gas and the HF gas may be supplied to the substrate W in the first process and the third process, respectively. Furthermore, in processing the substrate W, although an example in which the front surface on which the space 10 opens facing upward has been shown, the present disclosure is not limited to an apparatus configuration in which the substrate W is held with the front surface facing upward during processing. In addition, the present disclosure is not limited to formation of the SiOₓ film 14 on the entire wall surface forming the space 10, and the present technology may be used to form the SiOₓ film 14 on only a part of the wall surface and to etch that SiOₓ film 14.

Further, the present disclosure is not limited to processing the substrate W once in each of the processing modules 7a and 7b, and the substrate W may be repeatedly transferred between the processing modules 7a and 7b, for example, the processing module 7a → processing module 7b → processing module 7a → processing module 7b, and so on, to be processed. In other words, modification into the reaction product (AFS) 15 at each location on the wall surface of the space 10 and removal of the reaction product (AFS) 15 may be repeatedly performed. By doing so, even when the target film (SiOₓ film 14) is relatively thick, the target film (SiOₓ film 14) may be removed.

Furthermore, while the substrate processing method of the present disclosure has been described focusing on the removal of the SiOₓ film as the target film, the present disclosure is not limited thereto and the substrate processing method may be used to remove films of other compositions. In this case, instead of the HF gas and the NH₃ gas as the process gases, other process gases suitable for removing the target film can be used.

The space 10 of the substrate W, in which the substrate processing of the present disclosure is performed, is not limited to being composed of the first recess 12 and the plurality of second recesses 13 arranged as described above. For example, the second recesses 13 may not be positioned or oriented relative to the first recess 12 as previously described, and the space may have another shape in which the area of an inner wall surface is large and pressure loss is high, as in the present disclosure.

### Evaluation Test

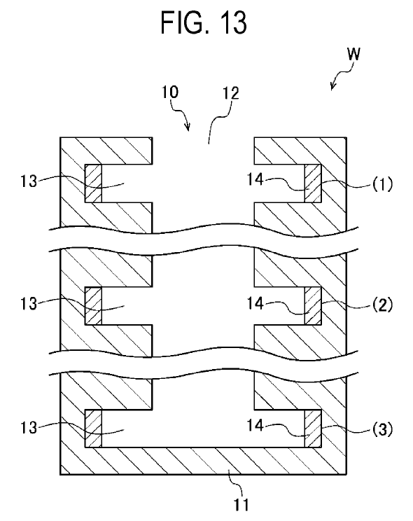

In the present evaluation test, the removal amount of the target film (SiOₓ film 14) on the inner wall surface of the substrate W was confirmed by performing each reaction process and removal process according to an embodiment and a comparative example different from the embodiment. First, after previously forming the space 10 in the space forming layer 11 of each of two bare wafers, which are silicon substrates, the space 10 was sufficiently exposed to the atmospheric environment to oxidize the wall surface of the space 10. FIG. 13 is a longitudinal cross-sectional side view illustrating the space forming layer 11 of the substrate W before the evaluation test, in which illustration of the target film (SiOₓ film 14) other than the target film (SiOₓ film 14) at the terminal ends of the second recesses 13 is omitted.

On one substrate, as the embodiment, the same reaction and removal processes as in the above-described embodiment were performed, and on the other substrate, as the comparative example, processes different from the embodiment were performed. In the comparative example, a cycle process was performed the same number of times as in the embodiment. The cycle process of the comparative example was performed by simultaneously performing the reaction process and the removal process. That is, the reaction process and the processing process were performed within the same processing container, and the temperature of the substrate W was set to 175 degrees C, which is higher than a sublimation temperature of the reaction product (AFS), so that the reaction product (AFS) formed during the reaction process was immediately sublimated. Furthermore, in the comparative example, the HF gas was not supplied by high-pressure discharge from the tank but instead was supplied at relatively low pressure for a long period of time. Thereafter, vacuum evacuation was performed for several seconds to sufficiently remove the HF gas. Subsequently, as in the embodiment, after the NH₃ gas was discharged at high pressure using the tank, vacuum evacuation was sufficiently performed, and the reaction product (AFS) was vaporized and removed.

In this evaluation test, after each processing of the embodiment and comparative example, the thickness of the remaining target film (SiOₓ film 14) was measured. As shown in FIG. 13, measurement locations of the SiOₓ film were a terminal end 1 of the uppermost second recess closest to the front surface opening, a terminal end 2 of the second recess 13 at a middle position in the vertical direction, and a terminal end 3 of the lowermost second recess 13. The thickness of the target film (SiOₓ film 14) was measured by measuring the length in a direction orthogonal to a side surface of each terminal end.

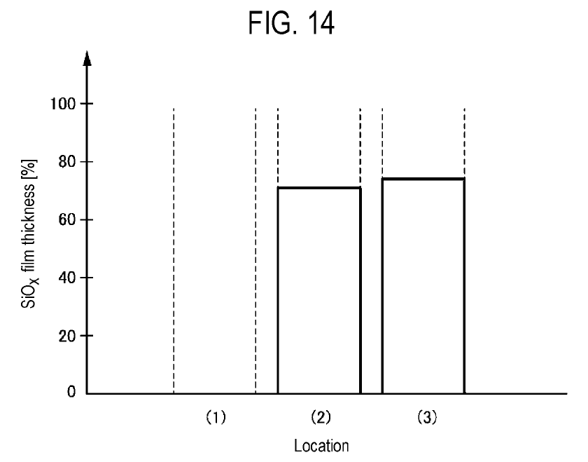

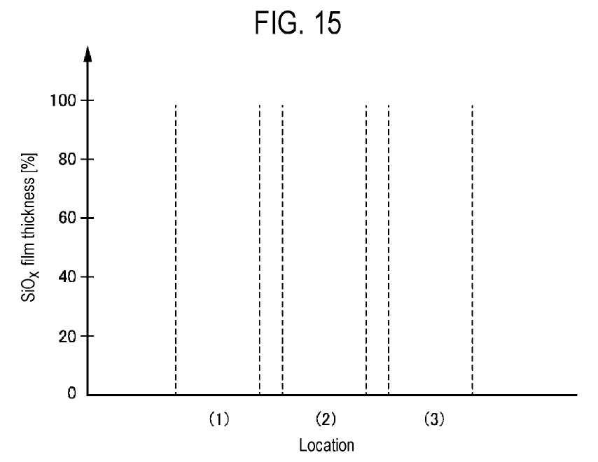

FIG. 14 illustrates the film thickness of the target film (SiOₓ film 14) at each location after an etching process in the comparative example, and FIG. 15 illustrates the film thickness of the target film (SiOₓ film 14) at each location after the etching process in the embodiment. In each figure, the film thickness is represented as a percentage of the film thickness of the target film (SiOₓ film 14) after processing relative to the thickness of the target film (SiOₓ film 14) before processing. The film thickness of the target film (SiOₓ film 14) after processing according to the comparative example became zero at the terminal end 1 of an upper portion but was 70% or more and less than 80% of the film thickness before processing at the terminal end 2 of a middle portion and the terminal end 3 of a lower portion. The film thickness at the terminal end 3 of the lower portion was slightly greater than that at the terminal end 2 of the middle portion (FIG. 14). From these results, according to substrate processing of the comparative example, it was estimated that, even when the cycle was repeatedly performed, the HF gas could not be sufficiently supplied to or adsorbed onto the lower side of the space 10, and therefore, the target film (SiOₓ film 14) remained thick.

In contrast, the film thickness of the target film (SiOₓ film 14) after processing according to the embodiment became zero (FIG. 15) at all of the terminal end 1 of the upper portion, the terminal end 2 of the middle portion, and the terminal end 3 of the lower portion. According to substrate processing of the embodiment, it was confirmed that, each gas was sufficiently supplied to and adsorbed onto the lower side of space 10 and the entire target film (SiOₓ film 14) was converted into the reaction product (AFS) in the reaction process, and the reaction product (AFS) was vaporized and removed in the removal process.

It should be noted that the embodiments disclosed herein are exemplary in all aspects and are not restrictive. The above-described embodiments may be omitted, replaced, or modified in various forms without departing from the scope and spirit of the appended claims.

According to the present disclosure in some embodiments, it is possible to remove a target film formed on a wall surface forming a space included in a substrate, over a widened range, the space being composed of a first recess opening at an upper surface of the substrate and a plurality of second recesses opening at different positions of the first recess.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing method, comprising:
a process of accommodating, in a processing container, a substrate having a space including a first recess opening at a front surface of the substrate and a plurality of second recesses opening at different positions of the first recess in a thickness direction of the substrate, wherein a wall surface forming the space has a target film;
a first process of supplying a first gas to the substrate inside the processing container from a first tank pressurized by storing the first gas;
a second process of exhausting an interior of the processing container in a state in which supply of the first gas into the processing container is stopped;
a third process of supplying a second gas to the substrate inside the processing container from a second tank pressurized by storing the second gas, the second gas reacting with the target film together with the first gas remaining in the space to generate a reaction product on the wall surface;
a fourth process of exhausting the interior of the processing container in a state in which supply of the second gas into the processing container is stopped;
a reaction process of repeating a cycle of sequentially performing the first process, the second process, the third process, and the fourth process so as to generate the reaction product from a front surface side toward a rear surface side of the substrate, and of setting a temperature of the substrate to a first temperature while repeating the cycle such that the reaction product formed during a previous cycle remains on the substrate during a subsequent cycle; and
a removal process of removing the reaction product as a gas by setting the temperature of the substrate after the reaction process is performed to a second temperature higher than the first temperature.

2. The substrate processing method of claim 1, wherein an execution time of the second process is shorter than an execution time of the fourth process.

3. The substrate processing method of claim 2, wherein the execution time of the second process is 0.1 seconds or less.

4. The substrate processing method of claim 1, wherein pressure inside the processing container in the fourth process is lower than pressure inside the processing container in each of the first process, the second process, and the third process.

5. The substrate processing method of claim 1, wherein the removal process is performed by accommodating the substrate inside a separate processing container different from the processing container.

6. The substrate processing method of claim 1, wherein the target film is composed of silicon oxide, one of the first gas and the second gas is hydrogen fluoride gas, and the other of the first gas and the second gas is ammonia gas or amine gas.

7. The substrate processing method of claim 6, wherein the first temperature is in a range of 0 degrees C or more and 60 degrees C or less.

8. A substrate processing apparatus, comprising:
a processing container configured to accommodate therein a substrate having a space including a first recess opening at a front surface of the substrate and a plurality of second recesses opening at different positions of the first recess in a thickness direction of the substrate, wherein a wall surface forming the space has a target film, and an interior of the processing container is exhausted;
a first temperature adjustor configured to adjust a temperature of the substrate within the processing container;
a first tank configured to be pressurized by storing a first gas;
a second tank configured to be pressurized by storing a second gas which reacts with the target film together with the first gas to generate a reaction product on the wall surface;
a first valve and a second valve opened to supply the first gas and the second gas from the first tank and the second tank, respectively, into the processing container;
a controller configured to generate a control signal so as to perform:
a first process of supplying the first gas to the substrate inside the processing container from the pressurized first tank;
a second process of exhausting the interior of the processing container in a state in which supply of the first gas into the processing container is stopped;
a third process of supplying the second gas from the pressurized second tank to the substrate inside the processing container in which the first gas remains in the space;
a fourth process of exhausting the interior of the processing container in a state in which supply of the second gas into the processing container is stopped; and
a reaction process of repeating a cycle of sequentially performing the first process, the second process, the third process, and the fourth process so as to generate the reaction product from a front surface side toward a rear surface side of the substrate, and of setting the temperature of the substrate to a first temperature while repeating the cycle such that the reaction product formed during a previous cycle remains on the substrate during a subsequent cycle, and
a second temperature adjustor configured to remove the reaction product as a gas by setting the temperature of the substrate after the reaction process is performed to a second temperature higher than the first temperature.
